(19) United States
(12) Patent Application Publication
(10) Pub. No.: US 2005/0180318 A1
(43) Pub. Date: Aug. 18, 2005

(54) Subordinate apparatus and superordinate apparatus

(75) Inventors: Tomoyuki Yamamoto, Kawasaki (JP); Masahiro Shioda, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 10/869,961

(22) Filed: Jun. 18, 2004

(30) Foreign Application Priority Data
Feb. 16, 2004 (JP) 2004-038042

(51) Int. Cl. H04J 3/14; H04L 1/00; G01R 31/08; G08C 15/00; H04L 12/26; G06F 11/00; H04J 1/16; H04L 12/56; H04L 12/28

(52) U.S. Cl. 370/219; 370/410

(57) ABSTRACT

The invention relates to a subordinate apparatus and a superordinate apparatus. The object thereof is to surely detecting an erroneous connection in a wiring between these apparatus and identifying an erroneously connected cable. A subordinate apparatus has an identifier acquiring section acquiring an identifier that is granted by a superordinate apparatus via a communication link that is formed via a first cable. When granted a new identifier via the communication link, the identifier acquiring section makes a first judgment as to whether there is an identifier granted prior to the new identifier. The identifier acquiring section nullifies the new identifier if there is an identifier granted prior to the new identifier.

### CROSS REFERENCE TO RELATED APPLICATION

This application is based upon and claims the benefit of priority from Japanese Patent Application No. 2004-038042, filed on Feb. 16, 2004, the entire contents of which are incorporated herein by reference.

### BACKGROUND OF THE INVENTION

1. Field of the Invention

The present invention relates to a subordinate apparatus that is connected to a superordinate apparatus via a prescribed wiring and has a prescribed function or a load by cooperating with or operating in parallel with the superordinate apparatus, as well as to a superordinate apparatus that initiatively controls over operation of such subordinate apparatus and over a system configuration.

2. Description of the Related Art

In recent years, transmission apparatus such as cross-connect apparatus have been required to be adaptable to diversification of communication services and to increase of demands and to expand the transmission capacity at a low cost. For the expansion, modification, and relocation of the transmission apparatus, these requirements are achieved by a building block scheme in which a plurality of transmission apparatus that have a proper transmission capacity and standardized configuration, and cooperate with each other via prescribed cables (optical fibers) are combined together.

FIG. 8 shows the configuration of an exemplary node apparatus that is a combination of a plurality of transmission apparatus (disclosed in Japanese Unexamined Patent Application Publication No. 9-65389 (Reference 1)).

As shown in FIG. 8, a node apparatus 10 is connected to three networks 20-0, 20-1, and 20-2 in a ring shape. The networks 20-0, 20-1, and 20-2 are provided with three node apparatus 20n-01 to 20n-03, two node apparatus 20n-11 and 20n-12, and three node apparatus 20n-21 to 20n-23, respectively.

The node apparatus 10 is composed of a wiring (described later) and three cross-connect apparatus 11-0 to 11-2 that are standardized in configuration and basically have a common configuration.

The cross-connect apparatus 11-0 is mounted on a main shelf of a prescribed rack and composed of the following components:

(1) A switch 12-0 having the following ports:
a particular port (hereinafter referred to as port L) to be connected to a network or a link (assumed here to be the network 20-0) whose transmission capacity is 100 gigabits/s or less.
Four ports (hereinafter referred to as ports J1-J4) to be connected to respective networks or links whose transmission capacity is 30 gigabits/s or less.
Two ports (hereinafter referred to as ports j1 and j2) to be connected to respective networks or links whose transmission capacity is 20 gigabits/s or less.

(2) A control unit 13-0 that leads control of the switch 12-0 and has two communication ports.

(3) Seven receptacles 14L-0, 14J-01 to 14J-04, 14j-01, and 14j-02 that are connected to the port L, the ports j1-J4, the port j1, and the port j2, respectively.

(4) Two receptacles 14C-01 and 14C-02 that are connected to the above-mentioned two communication ports, respectively.

The cross-connect apparatus 11-1 and 11-2 are mounted on two respective shelves (hereinafter referred to as first tributary shelf and second tributary shelf) of the above-mentioned rack.

The configurations of the cross-connect apparatus 11-1 and 11-2 are basically the same as the configuration of the cross-connect apparatus 11-0 and hence will not be described (the components of the cross-connect apparatus 11-1 and 11-2 are given the same reference symbols as those of the cross-connect apparatus 11-0 except that the first suffix is “1” or “2” instead of “0”).

The following cables are laid as the wiring among the cross-connect apparatus 11-0 through 11-2:
A cable 16L-0 having one end that is connected to a connector 15L-0 that is connected to the receptacle 14L-0 and the other end that is connected to preceding and following transmission sections of the network 20-0.
A cable 16L-1 having one end that is connected to a connector 15L-1 that is connected to the receptacle 14L-1 and the other end that is connected to preceding and following transmission sections of the network 20-1.
A cable 16L-2 having one end that is connected to a connector 15L-2 that is connected to the receptacle 14L-2 and the other end that is connected to preceding and following transmission sections of the network 20-2.
A cable 16J-1 having one end that is connected to a connector 15J-01 that is connected to the receptacle 14J-01 and the other end that is connected to a connector 15J-11 that is connected to the receptacle 14J-11.
A cable 16J-2 having one end that is connected to a connector 15J-02 that is connected to the receptacle 14J-02 and the other end that is connected to a connector 15J-12 that is connected to the receptacle 14J-12.
A cable 16J-3 having one end that is connected to a connector 15J-03 that is connected to the receptacle 14J-03 and the other end that is connected to a connector 15J-21 that is connected to the receptacle 14J-21.
A cable 16J-4 having one end that is connected to a connector 15J-04 that is connected to the receptacle 14J-04 and the other end that is connected to a connector 15J-22 that is connected to the receptacle 14J-22.
A cable 16j-1 having one end that is connected to a connector 15j-01 that is connected to the receptacle 14j-01 and the other end that is connected to a connector 15j-11 that is connected to the receptacle 14j-11.
A cable 16j-2 having one end that is connected to a connector 15j-02 that is connected to the receptacle 14j-02 and the other end that is connected to a connector 15j-21 that is connected to the receptacle 14j-21.
A cable 16C-1 having one end that is connected to a connector 15C-01 that is connected to the receptacle 14C-01 and the other end that is connected to a connector 15C-11 that is connected to the receptacle 14C-11.
A cable 16C-2 having one end that is connected to a connector 15C-02 that is connected to the receptacle 14C-02 and the other end that is connected to a connector 15C-12 that is connected to the receptacle 14C-12.

In the cross-connect apparatus 11-1 among the cross-connect apparatus 11-0 to 11-2 that are provided in the node apparatus 10, a link of 80 (=30+30+20) gigabits/s that is the sum of the transmission capacities of the ports J1, J2, and j1 is formed steadily between the port L and the ports J1, J2, and j1 of the switch 12-1 under processing that is performed by the control unit 13-1 on the basis of office data.

In the cross-connect apparatus 11-2, a link of 80 (=30+30+20) gigabits/s that is the sum of the transmission capacities of the ports J1, J2, and j1 is formed steadily between the port L and the ports J1, J2, and j1 of the switch 12-2 under processing that is performed by the control unit 13-2 on the basis of office data.

In the cross-connect apparatus 11-0, a link of 100 gigabits/s that is the transmission capacity of the port L is formed between the port L and the ports J1-J4 and the ports j1 and j2 of the switch 12-0 under processing that is performed by the control unit 13-0 on the basis of office data.

Therefore, in the node apparatus 10, the three cross-connect apparatus 11-0 to 11-2 that have standardized configuration cooperating with each other realizes desired cross-connection between the large-capacity networks 20-0, 20-1, and 20-2 at a low cost on the basis of office data through cooperation, via the wiring, as long as the wiring is proper.

In the above conventional example (Reference 1), the larger the number of cables or the number of cross-connect apparatuses connected to the cables is, the greater the possibility at which erroneous connection to the cables occurs and the amount of manpower necessary for installation thereof.

In general, manual inspection is needed for finding such an erroneous connection to eliminate it. This often leads to a delay in schedule and a cost increase not only in new installation of the cross-connect apparatus but also in expansion, modification, or relocation thereof.

Applying the technique disclosed in the above-mentioned Reference 1 makes it possible to reduce the delay in schedule and cost increase only if the main shelf informs each tributary shelf of a number to be assigned to it and an expanded tributary shelf automatically acquires the number.

However, with the appliance of the technique disclosed in Reference 1, a number of an expanded tributary shelf is set irreverent of its status. Therefore, if an erroneous connection occurs in the process of cable replacement work in response to, for example, a failure in the wiring after the tributary shelf starts its operation, the failure due to the erroneous connection may affect the entire system or substantially lower the transmission quality or service quality.

Further, the above-described conventional example and prior art technique cannot detect an erroneous connection in the wiring for principal signals that are delivered from the network 20-0 to one of the networks 20-1 and 20-2 or vice versa via the switches 12-0 to 12-2.

Therefore, even if proper paths are formed in the switches 12-0 to 12-2 of the cross-connects 11-0 to 11-2, normal cross-connection cannot be done among the networks 20-0, 20-1, and 20-2. Besides, the service quality or the secrecy of transmission information might be damaged continuously because the cross connect apparatus do not recognize the fact that the cross-connection is not normally done as well as it does not acquire information necessary to determine which cable is causing the failure.

### SUMMARY OF THE INVENTION

An object of the present invention is to provide a subordinate apparatus and a superordinate apparatus capable of detecting an erroneous connection in a wiring and identifying a cable having the erroneous connection quickly and reliably.

Another object of the invention is to surely improve, at a low cost, the performance and the total reliability of a system or an apparatus to which the invention is applied, without altering the basic hardware configuration.

Another object of the invention is to prevent a decrease in reliability of the subordinate apparatus and superordinate apparatus in the process of their maintenance and operation and to increase their work efficiency and reduce the cost for expansion, modification, and relocation thereof.

Another object of the invention is to give a superordinate apparatus and a subordinate apparatus facing to each other timings to recognize the occurrence of an erroneous connection in a transmission path for delivery of transmission information as well as criteria for the recognition of an erroneous connection.

Still another object of the invention is to deal with various states of cables when an erroneous connection occurs in the process of maintenance or operation of the subordinate and superordinate apparatuses.

Another object of the invention is to prevent unnecessary processing of a message relating to maintenance or operation of a transmission path as a cable when an erroneous connection occurs in the cable.

Yet another object of the invention is to prevent a decrease in the reliability of the subordinate apparatus and superordinate apparatus that would otherwise be caused by unnecessarily responding to transmission information delivered via a transmission path that is formed in the wiring having an erroneous connection, and to increase their work efficiency for the expansion, modification, and relocation thereof and reduce the cost for the same.

A further object of the invention is to standardize the procedure and the timing of adding each of expanded subordinate apparatuses to the system configuration unlike in a case that all subordinate apparatuses including an expanded one can be permitted to start their operation in parallel and asynchronously, and to standardize sequences not only for a start of the operation but also for their maintenance and operation including expansion and to increase the reliability thereof.

The invention will be summarized in the following.

In a first subordinate apparatus according to the invention, an identifier acquiring section acquires an identifier that is granted by a superordinate apparatus via a communication link formed via a first wiring. When granted an identifier via the communication link, the identifier acquiring section makes a first judgment as to whether there is an identifier granted prior to the new identifier. The identifier acquiring section nullifies the new identifier if a result of the first judgment is positive.

That is, an identifier precedingly granted by the superordinate apparatus via the communication link is maintained without being updated improperly even when an erroneous connection has occurred in a first cable as the communication link in the process of maintenance or operational work of the subordinate apparatus, for example. Accordingly, it is able to maintain the reliability of the subordinate apparatus and to improve the efficiency of works for its expansion, modification, and relocation and reduce the cost for the same.

In a second subordinate apparatus according to the invention, an identifier acquiring section acquires a common identifier that is granted by a superordinate apparatus via an active redundancy communication link formed via a first cable. When granted a new common identifier via the active redundancy communication link, the identifier acquiring section makes a first judgment as to whether there is a common identifier granted prior to the new common identifier. The identifier acquiring section nullifies the new common identifier if a result of the first judgment is positive.

A common identifier precedingly granted by the superordinate apparatus via a redundant communication link is maintained without being updated improperly even when an erroneous connection has occurred in the first cable as the communication link in the process of maintenance or operational work of the subordinate apparatus, for example. Therefore, it is able to maintain the reliability of the subordinate apparatus in the process of its maintenance and operational work and to improve the efficiency of works for its expansion, modification, and relocation and reduce the cost for the same.

In a third subordinate apparatus according to the invention, a first control section makes a second judgment as to whether the new identifier granted via the communication link coincides with the identifier granted prior to the new identifier, and nullifies information supplied via the communication link if a result of the second judgment is negative.

When an erroneous connection occurs in a first cable under the maintenance or operational work of the subordinate apparatus, and it causes the granting of a new identifier different from the one previously granted by the superordinate apparatus via the communication link as the first cable, for example, the third subordinate apparatus can avoid unnecessarily responding to the information supplied via this communication link. Therefore, it is able to maintain the reliability of the subordinate apparatus in the process of its maintenance and operational work and to improve the efficiency of works for its expansion, modification, and relocation and reduce the cost for the same.

In a fourth subordinate apparatus according to the invention, a first control section makes a second judgment as to whether the new common identifier granted via a redundant link coincides with the common identifier granted prior to the new common identifier, and nullifies information supplied via the communication link if a result of the second judgment is negative.

When an erroneous connection occurs in a first cable under the maintenance or operational work of the subordinate apparatus, and it causes the granting of a new common identifier different from the one previously granted by the superordinate apparatus via the communication link as the first cable, for example, the fourth subordinate apparatus can avoid unnecessarily responding to the information supplied via this communication link. Therefore, it is able to maintain the reliability of the subordinate apparatus in the process of its maintenance and operational work and to improve the efficiency of works for its expansion, modification, and relocation and reduce the cost for the same.

In a fifth subordinate apparatus according to the invention, a first transmission interface section interfaces with a transmission path as a second cable that is terminated by the superordinate apparatus or intervened by the superordinate apparatus as a relay node. A cable identifier delivering section delivers, to the superordinate apparatus, via the first transmission interface section and the second cable, an identifier granted by the superordinate apparatus via the communication link and unique identification information indicating the second cable.

That is, transmission information, which is delivered to the superordinate apparatus via the transmission path as a second cable, contains an identifier granted by the superordinate apparatus via the above-mentioned communication link and unique identification information indicating the second cable. Therefore, the superordinate apparatus is provided a timing to recognize an erroneous connection that has occurred in the transmission path for delivery of the transmission information as well as criteria for recognition of an erroneous connection.

In a sixth subordinate apparatus according to the invention, a second transmission interface section interfaces with a transmission path as a third cable that is terminated by the superordinate apparatus or intervened by the superordinate apparatus as a relay node. A second control section makes a third judgment as to whether transmission information delivered from the superordinate apparatus via the third cable and the second transmission interface section contains, in a prescribed format, an identifier granted by the superordinate apparatus via the communication link and unique identification information indicating the third cable, and establishes a system configuration that conforms to a result of the third judgment.

That is, the sixth subordinate apparatus makes a judgment on whether a third cable is normal or not on the basis of the contents of transmission information delivered from the superordinate apparatus via a transmission path as the third cable, and responds according to a result of the judgment. This makes it possible for the sixth subordinate apparatus to deal with various states of the third cable where an erroneous connection may occur under its maintenance or operational work.

In a seventh subordinate apparatus according to the invention, a third control section nullifies information supplied via the communication link if the transmission information delivered from the superordinate apparatus does not contain an identifier granted by the superordinate apparatus and unique identification information indicating the third cable in the prescribed format.

That is, when an erroneous connection occurs in a third cable as a transmission path, information delivered from the superordinate apparatus via the communication link is nullified even with no erroneous error in the first cable as the communication link. Therefore, while an erroneous connection is occurring in the third cable, the seventh subordinate apparatus can avoid processing unnecessary messages relating to maintenance or operation of the transmission path as the third cable.

In an eighth subordinate apparatus according to the invention, a communication control section discards the transmission information delivered from the superordinate apparatus or refraining from relaying it to a succeeding transmission section of the transmission path if it does not contain an identifier granted by the superordinate apparatus and unique identification information indicating the third cable in the prescribed format.

That is, the eighth subordinate apparatus regards transmission information delivered from the superordinate apparatus via a transmission path as effective only if no erroneous connection has occurred in the third cable as the transmission path. This prevents reduction in system reliability that would otherwise be caused by unnecessarily responding to transmission information delivered via the transmission path as the third cable having an erroneous connection. Further, it is possible to improve the efficiency of works for the expansion, modification, and relocation of the subordinate apparatus and reduce the cost for the same.

In a first superordinate apparatus according to the invention, an information exchanging section exchanges, with a subordinate apparatus, an identifier to be granted to the subordinate apparatus and information relating to operation of the subordinate apparatus. The exchange is made via a communication link which is formed via a first cable laid between the superordinate apparatus and the subordinate apparatus. A first judging section makes a first judgment as to whether an identifier delivered from the subordinate apparatus as information is an identifier to be granted to the subordinate apparatus. The information exchanging section nullifies the information if a result of the first judgment is negative.

When an erroneous connection occurs in a first cable under the maintenance or operational work of the super ordinate apparatus, and it causes the granting of a new identifier different from the one previously granted by the subordinate apparatus via the communication link as the first cable, for example, the first superordinate apparatus can avoid unnecessarily responding to the information supplied via this communication link. Therefore, it is able to prevent a reduction in the reliability of the superordinate apparatus in the process of its maintenance and operational work and to improve the efficiency of works for its expansion, modification, and relocation and reduce the cost for the same.

In a second superordinate apparatus according to the invention, an information exchanging section exchanges, with a subordinate apparatus, an identifier to be granted to the subordinate apparatus and information relating to operation of the subordinate apparatus. The exchange is made via an active redundancy communication link which is formed via a first cable laid between the superordinate apparatus and the subordinate apparatus. A first judging section makes a first judgment as to whether an identifier delivered from the subordinate apparatus as information is an identifier to be granted to the subordinate apparatus. The information exchanging section nullifies the information if a result of the first judgment is negative.

When an erroneous connection occurs in a first cable under the maintenance or operational work, and it causes the granting of a new identifier different from the one previously granted by the subordinate apparatus via the communication link as the first cable, for example, the first superordinate apparatus can avoid unnecessarily responding to the information supplied via this communication link. Therefore, it is able to prevent a reduction in the reliability of the superordinate apparatus in the process of its maintenance and operational work and to improve the efficiency of works for its expansion, modification, and relocation and reduce the cost for the same.

In a third superordinate apparatus according to the invention, a cable identifier delivering section delivers to the subordinate apparatus an identifier to be granted to the subordinate apparatus via the communication link and unique identification information indicating a second cable via a transmission path as a second cable that is terminated by the subordinate apparatus or intervened by the subordinate apparatus as a relay node.

That is, transmission information delivered to the subordinate apparatus via the transmission path as a second cable contains an identifier to be granted to the subordinate apparatus via the communication link and unique identification information indicating the second cable. Therefore, the subordinate apparatus is provided a timing to recognize an erroneous connection that has occurred under the maintenance or operational work in the transmission path for delivery of the transmission information, as well as criteria for recognition of an erroneous connection.

In a fourth superordinate apparatus according to the invention, a first control section makes a second judgment as to whether transmission information, which is delivered from the subordinate apparatus via a transmission path as a third cable and is terminated by the subordinate apparatus or intervened by the subordinate apparatus as a relay node, contains an identifier to be granted to the subordinate apparatus via the communication link and unique identification information indicating the third cable in a prescribed format, and establishes a system configuration that conforms to a result of the second judgment.

That is, the fourth superordinate apparatus makes a judgment on whether a third cable is normal or not on the basis of the contents of transmission information delivered from the subordinate apparatus via the transmission path as the third cable, and responds in conformity with a result of the judgment. This makes it possible for the fourth superordinate apparatus to deal with various states of the third cable where an erroneous connection may occur under its maintenance or operational work.

In a fifth superordinate apparatus according to the invention, a second control section nullifies information supplied via the communication link if the transmission information delivered from the subordinate apparatus does not contain an identifier to be granted to the subordinate apparatus via the communication link and unique identification information indicating the third cable in the prescribed format.

That is, while an erroneous connection is occurring in the third cable as a transmission path, the fifth superordinate apparatus nullifies information delivered from the subordinate apparatus via the communication link even if no erroneous error has occurred in the first cable as the communication link. Therefore, with the occurrence of an erroneous connection in the third cable, the fifth superordinate apparatus can avoid unnecessarily responding messages relating to the maintenance or operation of the transmission path as the third cable.

In a sixth superordinate apparatus according to the invention, a communication control section discards the transmission information delivered from the subordinate apparatus or refraining from relaying the transmission information to a succeeding transmission section for relay of the transmission information if the transmission information delivered from the subordinate apparatus does not contain an identifier to be granted to the subordinate apparatus via the communication link and unique identification information indicating the third cable in the prescribed format.

That is, the sixth superordinate apparatus regards the transmission information delivered from the subordinate apparatus via a transmission path as effective only if no erroneous connection has occurred in the third cable as the transmission path. This prevents reduction in the reliability of the superordinate apparatus that would otherwise be caused by unnecessarily responding to transmission information delivered via a transmission path as the third cable having an erroneous connection. This also makes it possible to improve the efficiency of works for its expansion, modification, and relocation and reduce the cost for the same.

In a seventh superordinate apparatus according to the invention, the communication link is a set of communication links as first cables which are laid between the superordinate apparatus and a plurality of subordinate apparatus separately. The transmission path is a set of transmission paths as second cables which are laid between the superordinate apparatus and the plurality of subordinate apparatus separately. The first control section adds an expanded one of the plurality of subordinate apparatus to a system configuration if an identifier delivered from each of the subordinate apparatuses as information is an identifier to be granted to the each subordinate apparatus, and transmission information delivered from the each subordinate apparatus contains the delivered identifier and unique identification information indicating the third cable in the prescribed format.

That is, an expanded subordinate apparatus is automatically permitted to start its operation after all of the other subordinate apparatuses have started their operation. Therefore, it is able to standardize the procedure and timing of adding each expanded subordinate apparatus to the system configuration unlike in a case that all the subordinate apparatuses including an expanded subordinate apparatus can be permitted to start their operations in parallel and asynchronously. It is also possible to improve the reliability of the superordinate apparatus as well as to standardize sequences associated with not only the starting of its operation but also its maintenance or operation including expansion.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a flowchart showing processes executed by a main shelf according to first and second embodiments of the invention;

FIG. 2 is a flowchart showing processes executed by a tributary shelf according to the first, second, and fourth embodiments of the invention;

FIG. 3 is a chart showing operations of the first to third embodiments of the invention;

FIG. 4 shows the structure of an identifier register;

FIG. 5 shows the structures of shelf identifier notices;

FIGS. 6A and 6B shows examples of erroneous connections of communication links and those of transmission paths, respectively;

FIG. 7 is a table showing exemplary shelf numbers of shelves that are configured redundantly; and

FIG. 8 shows the configuration of an exemplary node apparatus that is a combination of a plurality of transmission apparatus.

### DESCRIPTION OF THE PREFERRED EMBODIMENTS

Embodiments of the present invention will be hereinafter described in detail with reference to the drawings.

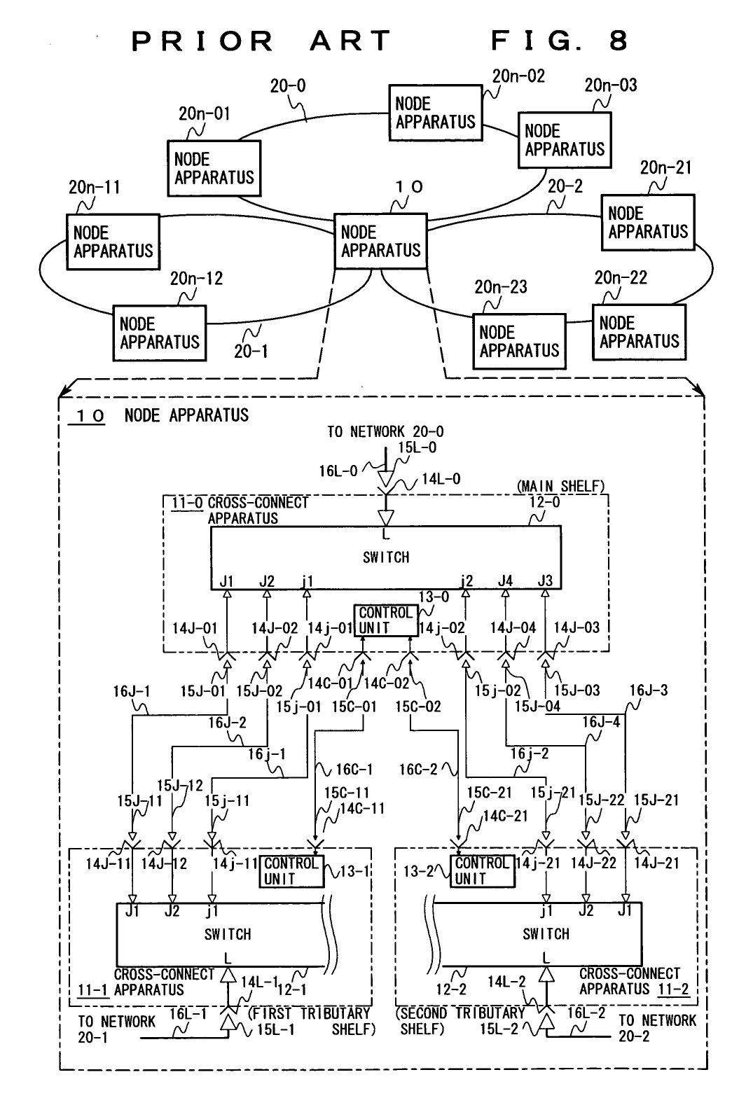

Each of the following embodiments of the invention is characterized by processing procedures that are made by the control units 13-0, 13-1, and 13-2 of the cross-connect apparatus 11-0, 11-1, and 11-2, and each of the embodiments employs basically the same hardware configuration as the configuration of the conventional example of FIG. 8.

In the following description, the control units 13-0, 13-1, and 13-2 of the cross-connect apparatus 11-0, 11-1, and 11-2 will be referred to as main shelf, first tributary shelf, and second tributary shelf, respectively. A tributary shelf that can be either of the first tributary shelf and the second tributary shelf will be referred to as nth tributary shelf.

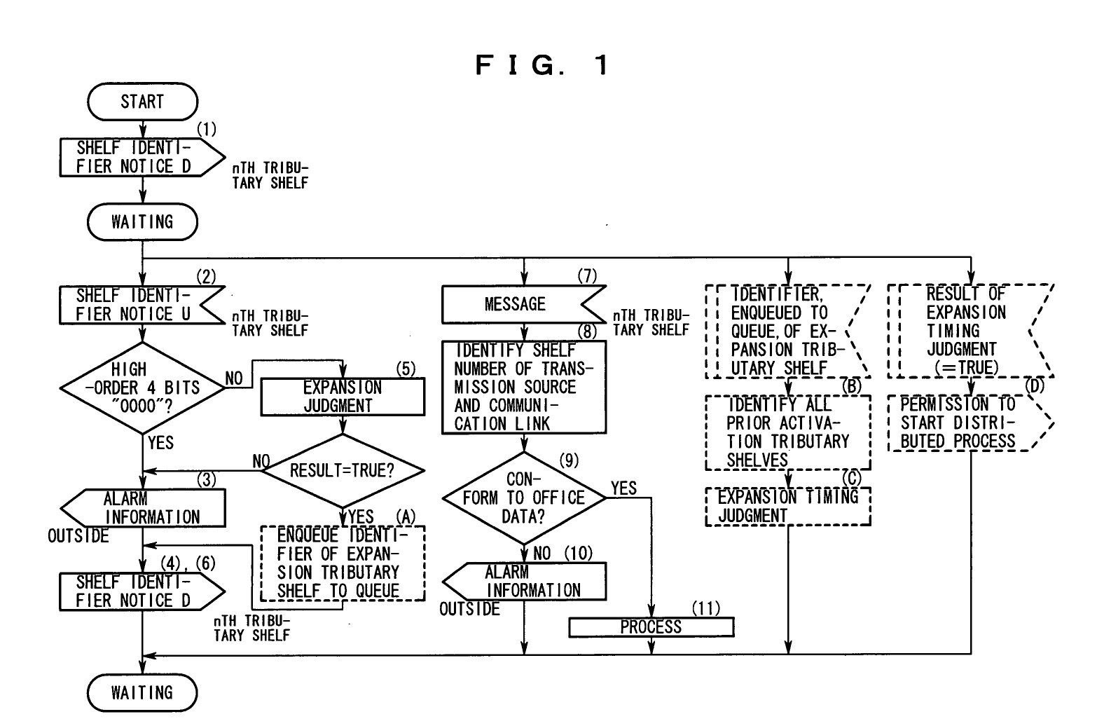

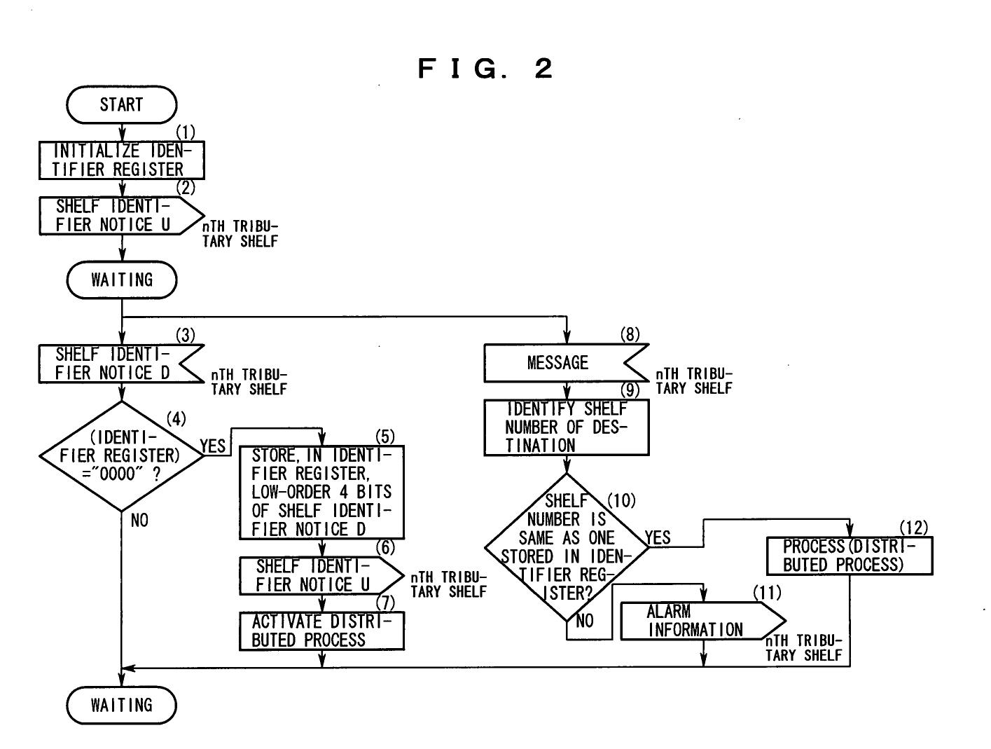

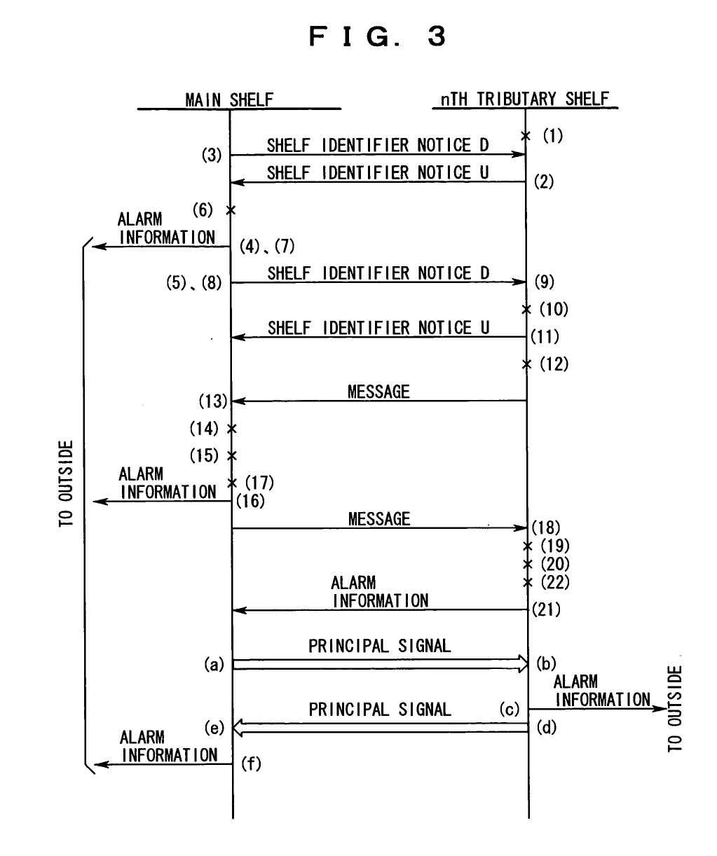

FIG. 1 is a flowchart showing processes executed by the main shelf according to first and second embodiments of the invention. FIG. 2 is a flowchart showing processes executed by the tributary shelf according to the first, second, and fourth embodiments of the invention. FIG. 3 is a chart showing operations of the first to third embodiments of the invention.

The operation of the first embodiment of the invention will be described below with reference to FIGS. 1-3, and 8.

The main shelf is given in advance, as office data, unique 4-bit identifiers (hereinafter referred to as shelf identifiers) “1110,” “0001,” and “0010” to be assigned to the main shelf itself, the first tributary shelf, and the second tributary shelf, respectively.

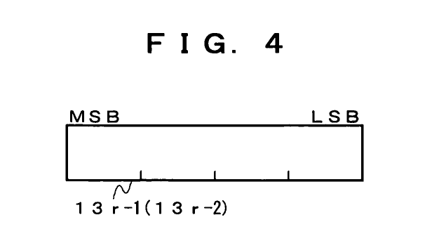

As shown in FIG. 4, the first tributary shelf and the second tributary shelf has respective identifier registers 13r-1 and 13r-2 to store a shelf identifier.

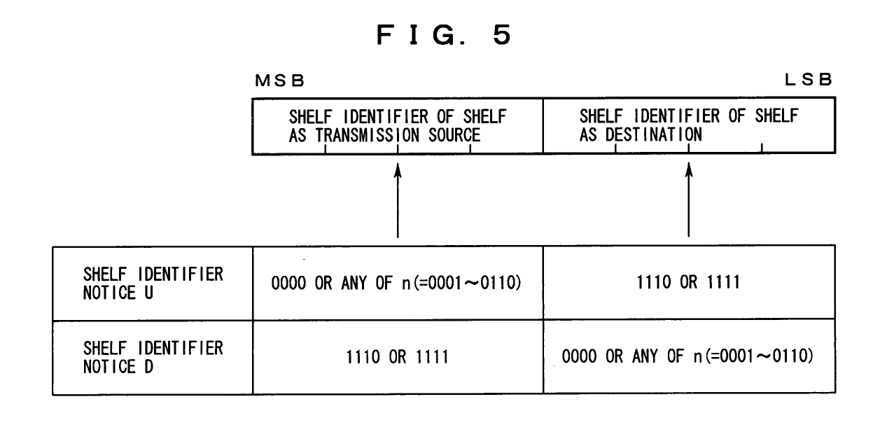

When started, the nth tributary shelf initializes the value of the identifier register 13r-n to “0000” (indicated by symbol (1) in FIG. 2 and symbol (1) in FIG. 3) and sends a shelf identifier notice U (in which the value (=0000) of the identifier register 13r-n and the shelf identifier (=1110) of the main shelf as a destination are packed as high-order 4 bits and low-order 4 bits, respectively) having the structure shown in FIG. 5 to an nth communication link to be formed between the nth tributary shelf and the main shelf via the cable 16C-n (indicated by symbol (2) in FIG. 2 and symbol (2) in FIG. 3).

When started, the main shelf sends a shelf identifier notice D (in which the shelf identifier (=1110) of the main shelf as a transmission source and the shelf identifier (=n) of the nth tributary shelf as a destination are packed as high-order 4 bits and low-order 4 bits, respectively) having the structure shown in FIG. 5 to the above-mentioned nth communication link (indicated by symbol (1) in FIG. 1 and symbol (3) in FIG. 3).

Among the values that the shelf identifiers can have, “0000” is a value that occurs under the hardware configuration in a case that the cable 16C-n has not been laid, as part of the wiring, between the main shelf and the nth tributary shelf and hence is not assigned to the main shelf or any tributary shelves.

When receiving, via the nth communication link, a shelf identifier notice U having, as high-order 4 bits, the shelf identifier of a certain tributary shelf or “0000” indicating that no shelf identifier has been granted (indicated by symbol (2) in FIG. 1), the main shelf performs the following processing (1) or (2):

(1) If the high-order 4 bits are “0000,” outputs alarm information containing information to that effect and that shelf identifier to the outside of the system (indicated by symbol (3) in FIG. 1 and symbol (4) in FIG. 3) and sends the above-mentioned shelf identifier notice D to the nth communication link (indicated by symbol (4) in FIG. 1 and symbol (5) in FIG. 3).

(2) If the high-order 4 bits are the shelf identifier of a certain tributary shelf (assumed here to be the shelf identifier of the nth tributary shelf), performs the following processing:
Acquires, as office data, a shelf identifier to be assigned to the nth tributary shelf that is located on the other side of the nth communication link.
Judges whether the above shelf identifier is the same as the high-order 4 bits of the shelf identifier notice U (hereinafter referred to as expansion judgment; indicated by symbol (5) in FIG. 1 and symbol (6) in FIG. 3).
If the result of the expansion judgment is that the shelf identifier is not the same as the high-order 4 bits of the shelf identifier notice U, outputs alarm information (may contain a related shelf identifier or cable identification information) to that effect to the outside of the system (indicated by symbol (3) in FIG. 1 and symbol (7) in FIG. 3).
Sends the above-mentioned shelf identifier notice D to the nth communication link irrespective of the result of the expansion judgment (indicated by symbol (6) in FIG. 1 and symbol (8) in FIG. 3).

When receiving the shelf identifier notice D (indicated by symbol (3) in FIG. 2), the nth tributary shelf judges whether the value of the identifier register 13r-n is “0000” (indicated by symbol (4) in FIG. 2 and symbol (9) in FIG. 3) and performs the following processing (1)-(3) only if the value of the identifier register 13r-n is “0000”.

(1) Stores, in the identifier register 13r-n, the shelf identifier (assumed here to be a binary number n that is not “0000” or “1110”) in the low-order 4 bits of the received shelf identifier notice D (indicated by symbol (5) in FIG. 2 and symbol (10) in FIG. 3).

(2) Sends the nth communication link a shelf identifier notice U (in which the shelf identifier (=n) stored in the identifier register 13r-n and the shelf identifier (=1110) of the main shelf as the destination are packed in the high-order 4 bits and the low-order 4 bits, respectively) (indicated by symbol (6) in FIG. 2 and symbol (11) in FIG. 3).

(3) Starts a process (hereinafter simply referred to as distributed process); includes cooperation with the main shelf and formation of a path to the switch 12-n) that is executed inherently by the nth tributary shelf and refers to the contents of the identifier register 13r-n when necessary according to a prescribed procedure (indicated by symbol (7) in FIG. 2 and symbol (12) in FIG. 3).

That is, in the nth tributary shelf, if the effective shelf number that is in the low-order 4 bits of the shelf identifier notice D sent from the main shelf and is not equal to “0000” is already stored in the identifier register 13r-n, the contents of the identifier register 13r-n is not updated nor used for the above-mentioned process.

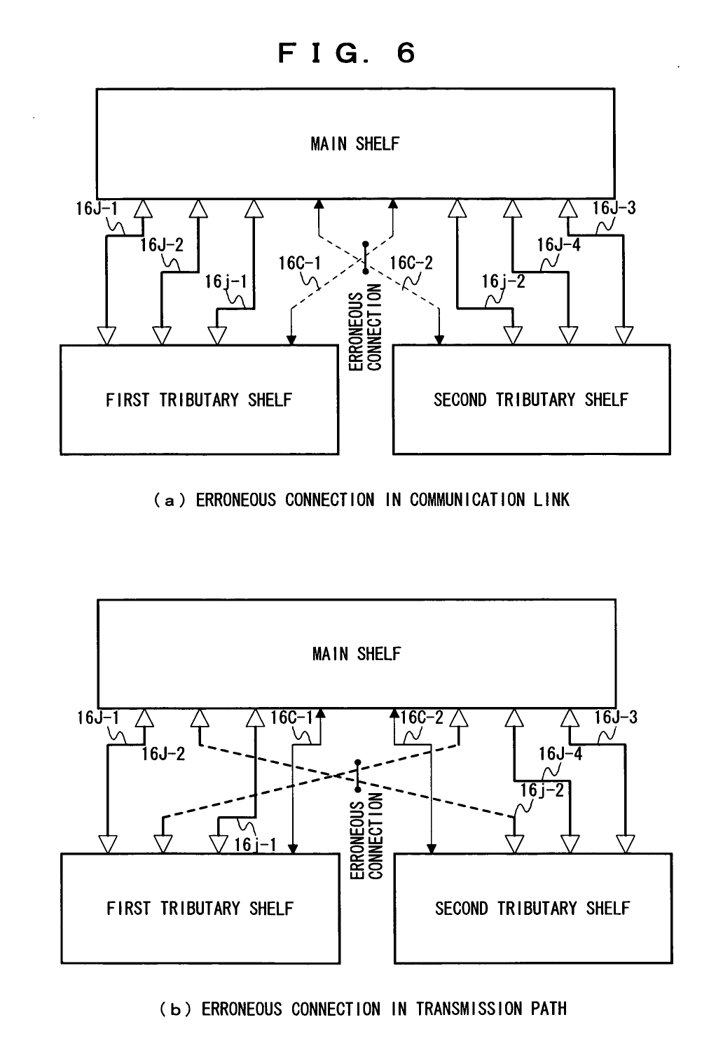

As described above, according to this embodiment, even if, for example, the cables 16C-1 and 16C-2 (connectors 15C-01, 15C-02, 15C-11, and 15C-21) to be laid between the main shelf and the first and second tributary shelves, respectively, are connected erroneously (including a case that a connection is not made) as indicated by broken lines in FIG. 6A in expansion, modification, or relocation engineering work or maintenance or operation work of the cross-connect apparatus, the regular shelf number that is already stored in the identifier register of each tributary shelf is maintained, that is, is not updated improperly.

Further, the erroneously connected cables and connectors are identified quickly and properly on the basis of alarm information (described above).

Therefore, this embodiment can keep a high total reliability of the cross-connect apparatus in the process of its maintenance and operation and can increase the efficiency of work for its expansion, modification, and relocation and reduce the cost for the same.

The operation of a second embodiment of the invention will be described below with reference to FIGS. 1-5, and 8.

This embodiment is characterized by the following processing procedure that is made by the main shelf (control unit 13-0) and the nth tributary shelf (control unit 13-n).

The main shelf and the nth tributary shelf exchange a message having such a prescribed format as to contain the shelf number of a shelf as a destination with each other via the communication link when necessary.

When receiving a certain message from the nth tributary shelf (indicated by symbol (7) in FIG. 1 and symbol (13) in FIG. 3), the main shelf performs the following processing before starting a process to be executed in response to the message:
Identifies a shelf number (indicating a transmission source) contained in the message and a communication link (for the sake of simplicity, it is assumed here to be, in a regular case, the nth communication link that is formed on the cable 16C-n) that was used for the transmission of the message (indicated by symbol (8) in FIG. 1 and symbol (14) in FIG. 3).
Judges whether the shelf number and the communication link conform to office data (indicated by symbol (9) in FIG. 1 and symbol (15) in FIG. 3).
If the judgment result is that the shelf number and the communication link do not conform to the office data, sends alarm information to that effect (containing the shelf number and an identifier of the communication link) to the outside of the system (indicated by symbol (10) in FIG. 1 and symbol (16) in FIG. 3), discards the message, and omits start of the process (indicated by symbol (11) in FIG. 1 and symbol (17) in FIG. 3) to be executed in response to the message.

On the other hand, when receiving a certain message from the main shelf (indicated by symbol (8) in FIG. 2 and symbol (18) in FIG. 3), the nth tributary shelf performs the following processing before starting a process to be executed in response to the message:
Identifies a shelf number (indicating a destination) that is contained in the message (indicated by symbol (9) in FIG. 2 and symbol (19) in FIG. 3).
Judges whether the shelf number is the same as the shelf number stored in the identifier register 13r-n (indicated by symbol (10) in FIG. 2 and symbol (20) in FIG. 3).
If the judgment result is that the shelf number is not the same as the shelf number stored in the identifier register 13r-n, sends alarm information to that effect (containing the shelf number and the shelf number stored in the identifier register 13r-n) to the main shelf via the communication link (or directly to the outside of the system) (indicated by symbol (11) in FIG. 2 and symbol (21) in FIG. 3), discards the message, and omits start of the process (indicated by symbol (12) in FIG. 2 and symbol (22) in FIG. 3) to be executed in response to the message.

That is, even if the cables 16C-1 and 16C-2 (connectors 15C-01, 15C-02, 15C-11, and 15C-21) to be laid between the main shelf and the first and second tributary shelves, respectively, are connected erroneously in expansion, modification, or relocation engineering work or maintenance or operation work, not only in the main shelf but also in each tributary shelf a process is prevented from being started unnecessarily in response to a message containing destination information that does not indicate the shelf concerned.

Therefore, this embodiment can increase the efficiency of works for expansion, modification, and relocation of the cross-connect apparatus and reduce the cost for the same, and can keep high reliability of its maintenance and operation.

The operation of a third embodiment of the invention will be described below with reference to FIGS. 1, 3, and 8.

The third embodiment is characterized by the following processing procedures that are made by the main shelf (control unit 13-0) and the nth tributary shelf (control unit 13-n) and operations of the switches 13-0 and 13-n that cooperate with each other under those processing procedures.

The nth tributary shelf has the following identifiers as office data:
unique identifiers J1-n, J2-n, and j1-n (hereinafter referred to as transmission channel identifiers) indicating transmission channels that are formed between the nth tributary shelf and the main shelf via the ports J1, J2, and j1 among the ports of the switch 12-n, respectively.
A shelf identifier “1110” (hereinafter referred to as main shelf identifier) of the main shelf that is located on the other side of the above transmission channels.

The main shelf has the following identifiers as office data:
unique identifiers J1-1, J2-1, J1-2, J2-2, j1-1, and j2-2 (hereinafter referred to as transmission channel identifiers as mentioned above because they are obtained by substituting “1” and “2” into n of the above-mentioned identifiers J1-n, J2-n, and j1-n) indicating transmission channels that are formed between the main shelf and the tributary shelves that are located on the other side of the ports J1-J4, j1, and j2 among the ports of the switch 12-0, respectively.
Shelf identifiers “0001,” “0010,” . . . (hereinafter referred to as tributary shelf identifiers) of tributary shelves that are located on the other side of the above transmission channels.

In the main shelf, the switch 12-0 adds the following identifiers to transmission information to be transmitted, as a principal signal, to a tributary shelf (assumed here to be the nth tributary shelf) for which granting of a shelf identifier has completed via each of the transmission channels formed between the main shelf and the nth tributary shelf (indicated by symbol (a) in FIG. 3).
The tributary shelf identifier indicating the nth tributary shelf.
The transmission channel identifier indicating the transmission channel concerned.

In the nth tributary shelf, the switch 12-n performs the following processing on transmission information that is received from the main shelf via such a transmission channel (indicated by symbol (b) in FIG. 3).
Acquires the transmission channel identifier and the tributary shelf identifier that are contained in the transmission information.
Judges whether the acquired transmission channel identifier is the same as the transmission channel identifier of the transmission channel concerned that is given as office data and the acquired tributary shelf identifier is the same as the shelf number stored in the identifier register 13r-n.
Validates the transmission information only if the acquired transmission channel identifier is the same as the transmission channel identifier of the transmission channel concerned and the acquired tributary shelf identifier is the same as the shelf number stored in the identifier register 13r-n.

If the acquired transmission channel identifier is the same as the transmission channel identifier of the transmission channel concerned but the acquired tributary shelf identifier is not the same as the shelf number stored in the identifier register 13r-n, the switch 12-n discards the transmission information and outputs alarm information containing information to that effect and the acquired transmission channel identifier and tributary shelf identifier to the outside of the system (indicated by symbol (c) in FIG. 3).

Such transmission information may be discarded by any of the following pieces of processing that comply with a desired transmission scheme and multiple access scheme:
Where the synchronous digital hierarchy scheme or some other STM is employed, a bit string indicating a peculiar state such as a silent state is inserted in a prescribed field of an SDH frame to be sent to the following transmission section.
Where an ATM is employed, received transmission information is discarded directly or execution of all or part of processes is omitted.

In the nth tributary shelf, in a state that a shelf identifier granted by the main shelf is stored in the identifier register 13r-n, the switch 12-n adds the following identifiers to transmission information to be sent, as a principal signal, to the main shelf via each transmission channel formed between the nth tributary shelf and the main shelf (indicated by symbol (d) in FIG. 3):
The shelf identifier stored in the identifier register 13r-n.
The transmission channel identifier indicating the transmission channel concerned.

In the main shelf, the switch 12-0 performs the following processing on transmission information that is received from the nth tributary shelf via such a transmission channel (indicated by symbol (e) in FIG. 3):
Acquires the transmission channel identifier and the shelf identifier that are contained in the transmission information.
Judges whether the acquired transmission channel identifier is the same as the transmission channel identifier of the transmission channel concerned that is given as office data and the acquired shelf identifier is the same as the shelf identifier of the nth tributary shelf concerned that is given as office data.
Validates the transmission information only if the acquired transmission channel identifier is the same as the transmission channel identifier of the transmission channel concerned and the acquired shelf identifier is the same as the shelf identifier of the nth tributary shelf concerned that is given as office data.

If the acquired transmission channel identifier is the same as the transmission channel identifier of the transmission channel concerned but the acquired shelf identifier is not the same as the shelf identifier of the nth tributary shelf concerned that is given as office data, the switch 12-0 discards the transmission information and outputs alarm information containing information to that effect and the acquired transmission channel identifier and shelf identifier to the outside of the system (indicated by symbol (f) in FIG. 3).

That is, a principal signal to be delivered from one of the main shelf to the nth tributary shelf to another is transmitted as transmission information containing a shelf identifier that has been granted to the nth tributary shelf and a transmission channel identifier indicating a transmission channel (one of the cables 16J-1 to 16J-4, 16j-1, and 16j-2) that is used for the delivery of the principal signal. A receiving end of such a principal signal judges whether the transmission information is regular information on the basis of whether the shelf identifier and the transmission channel identifier conform to related office data.

A shelf identifier and a transmission channel identifier that are effective in identifying a position of an erroneous connection for which the result of the above judgment is that a principal signal is not a regular one are acquired automatically and quickly and provided as alarm information.

Therefore, for example, in a state that erroneous connections have occurred as indicated by broken lines in FIG. 6B, the erroneous connections can be detected and cables etc. concerned can be identified with high reliability and the transmission quality, the secrecy of transmission information, and the total reliability can be made higher than in the conventional example in which the above-described judgments are not performed.

A fourth embodiment of the invention will be described below with reference to FIGS. 1 and 8.

This embodiment is characterized by the following processing procedures that are made by the main shelf and each tributary shelf.

Each of the first tributary shelf and the second tributary shelf refrains from starting a distributed process until receiving permission to start the distributed process from the main shelf in the form of a message (described later).

On the other hand, every time the main shelf finds, in the above-described expansion judgment, a tributary shelf (hereinafter referred to as expansion tributary shelf) whose shelf identifier is equal to the value of the high-order 4 bits of a shelf identifier notice U concerned, the main shelf enqueues the identifier of this expansion tributary shelf into a queue (indicated by symbol (A) in FIG. 1).

Further, the main shelf performs the following processing for the identifiers of expansion tributary shelves in the queue:
(a) Acquires the identifier of the first expansion tributary shelf in the queue.
(b) Identifies all other tributary shelves (hereinafter referred to as prior activation tributary shelves) for which a distributed process was started before start of a distributed process for the first expansion tributary shelf (indicated by symbol (B) in FIG. 1).
(c) Judges, for each of the prior activation tributary shelves, whether the results of all the judgments other than the expansion judgment that are made by the main shelf in each of the first to third embodiments are affirmative (hereinafter referred to as expansion timing judgment; indicated by symbol (C) in FIG. 1).
(d) Permits the expansion tributary shelf to start the distributed process by sending it a message (described above) when the results of the expansion timing judgment has become affirmative, that is, the results of all the judgments other than the expansion judgment have become affirmative (indicated by symbol (D) in FIG. 1).
(e) Repeats steps (a)-(d) for the other expansion tributary shelves in the queue.

That is, each expansion tributary shelf is automatically permitted to start a distributed process when all prior activation tributary shelves have started distributed processes.

Therefore, according to this embodiment, it is possible to standardize the procedure and timing of adding each expansion tributary shelf to the system configuration unlike in a case that a plurality of expansion tributary shelves can start distributed processes in parallel and asynchronously. Not only sequences for a start period but also those for maintenance and operation including expansion can be standardized and the total reliability can be increased.

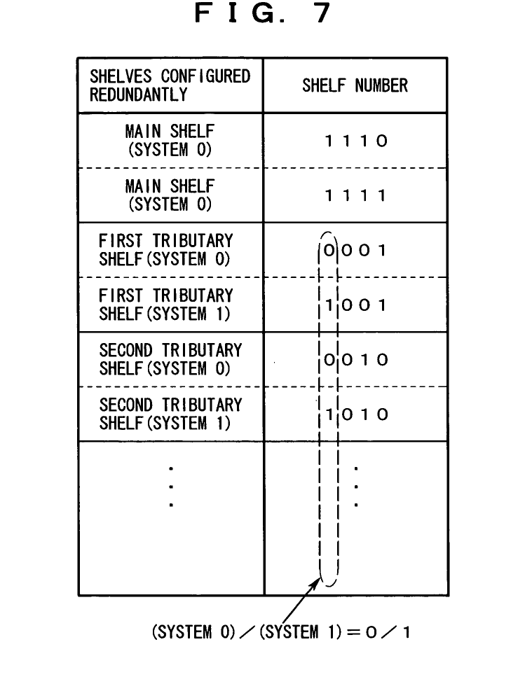

In each of the above embodiments, none of the main shelf and the tributary shelves are configured redundantly. However, the invention is not limited to such a configuration. For example, as shown in FIG. 7, the main shelf and the tributary shelves may be configured redundantly according to any scheme as long as all of the main shelf and the tributary shelves are granted unique shelf numbers and a system including main shelf and the tributary shelves is configured properly.

Each of the above embodiments is such that the invention is applied to the cross-connect apparatus that is compatible with the synchronous digital hierarchy scheme and in which loads and functions are distributed in a desired form. However, the invention is not limited to such a transmission apparatus and can be applied to a variety of apparatus each of which is a combination of a plurality of shelves or packages (modules) that are mounted on a rack or shelves and cooperate with each other via communication links and transmission channels (implemented as wirings that are connected to each other via detachable connectors or IDFs (intermediate distributing frames)).

Further, in each of the above embodiments, the communication links are formed via the different cables 16C-1 and 16C-2 and the transmission channels are formed via the cables 16J-1 to 16J-4, 16j-1 and 16j-2 that are different from the cables 16C-1 and 16C-2. However, all or part of the communication links and the transmission channels may be formed either via different cables (including optical fibers) or via a single cable that complies with a prescribed multiple access scheme.

The invention is not limited to the above embodiments and various modifications may be made without departing from the spirit and scope of the invention. Any improvement may be made in part or all of the components.

1. A subordinate apparatus comprising an identifier acquiring section that acquires an identifier that is granted by a superordinate apparatus via a communication link that is formed via a first cable, wherein:
upon granted a new identifier via said communication link, said identifier acquiring section makes a first judgment as to whether there is an identifier granted prior to the new identifier, and nullifies the new identifier if a result of the first judgment is positive.

2. A subordinate apparatus comprising an identifier acquiring section that acquires a common identifier that is granted by a superordinate apparatus via an active redundancy communication link that is formed via a first cable, wherein:
upon granted a new common identifier via said active redundancy communication link, said identifier acquiring section makes a first judgment as to whether there is a common identifier granted prior to the new common identifier, and nullifies the new common identifier if a result of the first judgment is positive.

3. The subordinate apparatus according to claim 1, further comprising a first control section that makes a second judgment as to whether the new identifier granted via said communication link coincides with the identifier granted prior to the new identifier, and nullifies information supplied via said communication link if a result of the second judgment is negative.

4. The subordinate apparatus according to claim 2, further comprising a first control section that makes a second judgment as to whether the new common identifier granted via said active redundancy communication link coincides with the common identifier granted prior to the new common identifier, and nullifies information supplied via said active redundancy communication link if a result of the second judgment is negative.

5. The subordinate apparatus according to claim 1, further comprising:
a first transmission interface section that interfaces with a transmission path as a second cable that is terminated by the superordinate apparatus or intervened by the superordinate apparatus as a relay node; and
a cable identifier delivering section that delivers an identifier and unique identification information to the superordinate apparatus via said first transmission interface section and the second cable, the identifier being granted by the superordinate apparatus via said communication link, the unique identification information indicating the second cable.

6. The subordinate apparatus according to claim 2, further comprising:
a first transmission interface section that interfaces with a transmission path as a second cable that is terminated by the superordinate apparatus or intervened by the superordinate apparatus as a relay node; and
a cable identifier delivering section that delivers an identifier and unique identification information to the superordinate apparatus via said first transmission interface section and the second cable, the identifier being granted by the superordinate apparatus via said communication link, the unique identification information indicating the second cable.

7. The subordinate apparatus according to claim 1, further comprising:
a second transmission interface section that interfaces with a transmission path as a third cable that is terminated by the superordinate apparatus or intervened by the superordinate apparatus as a relay node; and
a second control section that makes a third judgment as to whether transmission information delivered from the superordinate apparatus via the third cable and said second transmission interface section contains, in a prescribed format, the identifier granted by the superordinate apparatus via said communication link and unique identification information indicating the third cable, and establishes a system configuration in conformity wit a result of the third judgment.

8. The subordinate apparatus according to claim 2, further comprising:
a second transmission interface section that interfaces with a transmission path as a third cable that is terminated by the superordinate apparatus or intervened by the superordinate apparatus as a relay node; and
a second control section that makes a third judgment as to whether transmission information delivered from the superordinate apparatus via the third cable and said second transmission interface section contains, in a prescribed format, the identifier granted by the superordinate apparatus via said communication link and unique identification information indicating the third cable, and establishes a system configuration in conformity wit a result of the third judgment.

9. The subordinate apparatus according to claim 7, further comprising a third control section that nullifies information supplied via said communication link if a result of the third judgment is negative.

10. The subordinate apparatus according to claim 8, further comprising a third control section that nullifies information supplied via said communication link if a result of the third judgment is negative.

11. The subordinate apparatus according to claim 7, further comprising a communication control section that discards the transmission information delivered from the superordinate apparatus or refrains from relaying the transmission information to a succeeding transmission section of the transmission path if a result of the third judgment is negative.

12. The subordinate apparatus according to claim 8, further comprising a communication control section that discards the transmission information delivered from the superordinate apparatus or refrains from relaying the transmission information to a succeeding transmission section of the transmission path if a result of the third judgment is negative.

13. A superordinate apparatus comprising:
an information exchanging section that exchanges an identifier and information with a subordinate apparatus via a communication link which is formed via a first cable laid between the superordinate apparatus and the subordinate apparatus, the identifier being to be granted to the subordinate apparatus, the information relating to operation of the subordinate apparatus; and
a first judging section that makes a first judgment as to whether an identifier delivered from the subordinate apparatus as the information is an identifier to be granted to the subordinate apparatus, wherein
said information exchanging section nullifies the information if a result of the first judgment is negative.

14. A superordinate apparatus comprising:
an information exchanging section that exchanges an identifier and information with a subordinate apparatus via an active redundancy communication link that is formed via a first cable laid between the superordinate apparatus and the subordinate apparatus, the identifier being to be granted to the subordinate apparatus, the information relating to operation of the subordinate apparatus; and
a first judging section that makes a first judgment as to whether an identifier delivered from the subordinate apparatus as the information is an identifier to be granted to the subordinate apparatus, wherein
said information exchanging section nullifies the information if a result of the first judgment is negative.

15. The superordinate apparatus according to claim 13, further comprising a cable identifier delivering section that delivers an identifier and unique identification information to the subordinate apparatus via a transmission path as a second cable that is terminated by the subordinate apparatus or intervened by the subordinate apparatus as a relay node, the identifier being to be granted to the subordinate apparatus via the communication link, the unique identification information indicating the second cable.

16. The superordinate apparatus according to claim 14, further comprising a cable identifier delivering section that delivers an identifier and unique identification information to the subordinate apparatus via a transmission path as a second cable that is terminated by the subordinate apparatus or intervened by the subordinate apparatus as a relay node, the identifier being to be granted to the subordinate apparatus via the communication link, the unique identification information indicating the second cable.

17. The superordinate apparatus according to claim 13, further comprising a first control section that makes a second judgment as to whether transmission information contains, in a prescribed format, an identifier to be granted to the subordinate apparatus via said communication link and unique identification information, and establishes a system configuration in conformity with a result of the second judgment, the transmission information being delivered from the subordinate apparatus via a transmission path as a third cable that is terminated by the subordinate apparatus or intervened by the subordinate apparatus as a relay node, the unique identification information indicating the third cable.

18. The superordinate apparatus according to claim 14, further comprising a first control section that makes a second judgment as to whether transmission information contains, in a prescribed format, an identifier to be granted to the subordinate apparatus via said communication link and unique identification information, and establishes a system configuration in conformity with a result of the second judgment, the transmission information being delivered from the subordinate apparatus via a transmission path as a third cable that is terminated by the subordinate apparatus or intervened by the subordinate apparatus as a relay node, the unique identification information indicating the third cable.

19. The superordinate apparatus according to claim 17, further comprising a second control section that nullifies information supplied via said communication link if a result of the second judgment is negative.

20. The superordinate apparatus according to claim 18, further comprising a second control section that nullifies information supplied via said communication link if a result of the second judgment is negative.

21. The superordinate apparatus according to claim 17, further comprising a communication control section that discards the transmission information delivered from the subordinate apparatus or refrains from relaying the transmission information to a succeeding transmission section of the transmission channel if a result of the second judgment is negative.

22. The superordinate apparatus according to claim 18, further comprising a communication control section that discards the transmission information delivered from the subordinate apparatus or refrains from relaying the transmission information to a succeeding transmission section of the transmission channel if a result of the second judgment is negative.

23. The superordinate apparatus according to claim 17, wherein:
said communication link is a set of communication links as first cables laid between the superordinate apparatus and a plurality of subordinate apparatuses;
said transmission path is a set of transmission paths as second cables laid between the superordinate apparatus and said plurality of subordinate apparatuses; and
said first control section makes a fourth judgment as to whether an identifier delivered from each of said subordinate apparatuses is an identifier to be granted to each of said subordinate apparatuses and whether the transmission information delivered from each of said subordinate apparatuses contains, in the prescribed format, the identifier and the unique identification information indicating the third cable, and adds an expanded one of said subordinate apparatuses to a system configuration if a result of the fourth judgment is positive.
